(19) United States
(12) Patent Application Publication
(10) Pub. No.: US 2025/0160191 A1
(43) Pub. Date: May 15, 2025

(54) SPUTTERING APPARATUS AND DISPLAY DEVICE USING THE SAME

(71) Applicant: Samsung Display Co., LTD., Yongin-si (KR)

(72) Inventors: Min Jae JEONG, Yongin-si (KR); Jae Yong KA, Yongin-si (KR); Jin Ho HWANG, Yongin-si (KR)

(73) Assignee: Samsung Display Co., LTD., Yongin-si (KR)

(21) Appl. No.: 18/735,564

(22) Filed: Jun. 6, 2024

(30) Foreign Application Priority Data
Nov. 14, 2023 (KR) 10-2023-0156882

(51) Int. Cl. H10K 71/60; C23C 14/34; C23C 14/35; H10K 59/12; H10K 59/80

(52) U.S. Cl. CPC H10K 71/60; C23C 14/3407; C23C 14/35; H10K 59/1201; H10K 59/80521

(57) ABSTRACT

A sputtering apparatus includes a chamber in which a display device is placed and a deposition process is performed on the display device, a gas supply part supplying plasma gas into the chamber, a first target disposed in the chamber and facing the display device, and a plurality of first magnet members disposed inside the first target. The first target includes a first surface facing the display device and a second surface opposite the first surface and facing the plurality of first magnet members, and the first target further includes hollows and protrusions alternately repeated on the first surface.

### CROSS-REFERENCE TO RELATED APPLICATION(S)

This application claims priority to and benefit of Korean Patent Application No. 10-2023-0156882 under 35 U.S.C. § 119, filed on Nov. 14, 2023, in the Korean Intellectual Property Office (KIPO), the entire contents of which are incorporated herein by reference.

### BACKGROUND

### 1. Technical Field

The disclosure relates to a sputtering apparatus and a display device using the same.

### 2. Description of the Related Art

Display devices are becoming increasingly important with the development of multimedia. Accordingly, various types of display devices such as liquid crystal displays (LCDs) and organic light emitting displays (OLEDs) are being used.

To manufacture a display device, a process of forming and patterning a number of thin films is performed. To form a fine pattern by patterning a thin film, it is necessary to form an undamaged, high-quality thin film. There are various methods of forming a thin film, such as chemical vapor deposition, atomic layer deposition, and sputtering, depending on the material of the thin film or the purpose of forming the thin film. Among these methods, sputtering is a type of vacuum deposition method. It is a deposition method in which a gas such as argon is accelerated by generating plasma at a relatively low pressure so that the gas collides with a target to eject molecules, thereby forming a film on a nearby substrate.

### SUMMARY

Aspects of the disclosure provide a sputtering apparatus with improved plasma density and a display device using the sputtering apparatus.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment of the disclosure, a sputtering apparatus may include a chamber in which a display device is placed and a deposition process is performed on the display device, a gas supply part supplying plasma gas into the chamber, a first target disposed in the chamber and facing the display device, and a plurality of first magnet members disposed inside the first target. The first target may include a first surface facing the display device and a second surface opposite the first surface and facing the plurality of first magnet members, and the first target may further include hollows and protrusions alternately repeated on the first surface.

In embodiment, the first target may have a long cylindrical shape, and the first surface may have a cogwheel shape.

In embodiment, the first target may include a metal for forming a cathode of the display device.

In embodiment, the first target may include a metal for forming a transparent or translucent thin-film electrode.

In embodiment, the first target may function as a cathode.

In embodiment, the first target may have cathode walls facing each other by neighboring ones of the protrusions on the first surface.

In embodiment, the first target may form a first magnetic field by the plurality of first magnet members, and a density of the plasma gas may increase around first magnetic field lines included in the first magnetic field.

In embodiment, the first target may form a hollow cathode effect by the cathode walls, and the density of the plasma gas may increase around the cathode walls.

In embodiment, the sputtering apparatus may further include a second target adjacent to the first target in a direction, and a plurality of second magnet members disposed inside the second target. The second target may include protrusions and hollows repeated on a surface of the second target.

In embodiment, the sputtering apparatus may further include an alternating current (AC) power device which connects the first target and the second target.

In embodiment, the display device may include a substrate including an emission area and a non-emission area, an anode on the emission area of the substrate, a pixel defining layer on the non-emission area of the substrate, a first bank layer on the pixel defining layer, a second bank layer located on the first bank layer and including a tip which protrudes over a side surface of the first bank layer toward the emission area,

a light emitting layer disposed on the anode and contacting the side surface of the first bank layer, and a cathode disposed on the light emitting layer and contacting the side surface of the first bank layer. An area of contact between the cathode and the side surface of the first bank layer may be adjusted by adjusting a pressure of the plasma gas inside the chamber.

In embodiment, the side surface of the first bank layer may include a first part in contact with the light emitting layer and a second part in contact with the cathode, and an area of the second part may be adjusted in a range of about 10% to about 95% of the side surface of the first bank layer.

According to an embodiment, a sputtering apparatus may include a chamber in which a display device is placed and a deposition process is performed on the display device, a target disposed in the chamber and facing the display device, a plurality of internal magnet members disposed inside the target, and a gas supply part injecting plasma gas into the target. The target may include a plurality of holes completely passing through the target.

In embodiment, the plasma gas may be released from the inside of the target to the display device through the plurality of holes of the target.

In embodiment, the target may further include a plurality of cathode walls neighboring each other in a direction with one of the plurality of holes interposed between adjacent ones of the plurality of cathode walls.

In embodiment, a hollow cathode effect may be formed between the adjacent ones of the plurality of cathode walls, and a density of the plasma gas increases adjacent to the plurality of cathode walls.

According to an embodiment, a sputtering method for forming a cathode in a display device using a sputtering apparatus may include maintaining an inside of a chamber in a vacuum state using a vacuum pump and injecting plasma gas by a gas supply part, forming plasma around a target by applying a cathode voltage to the target, sputtering the target by the plasma gas and depositing ionized particles of the target on the display device as the cathode, and adjusting characteristics of a deposition layer of the cathode by adjusting straightness of the ionized particles of the target by adjusting the pressure of the plasma gas. The target may include protrusions and hollows alternately repeated on a surface of the target to increase a density of the plasma gas.

In embodiment, the target may further include internal magnet members disposed in the target, and the density of the plasma gas may be increased by a magnetic field formed by the internal magnet members.

In embodiment, the target may have cathode walls formed facing each other by neighboring ones of the protrusions formed on a surface of the target facing the display device, and the density of the plasma gas may be increased around the cathode walls by a hollow cathode effect formed by neighboring ones of the cathode walls.

In embodiment, the straightness and directionality of the ionized particles that form the cathode may be controlled by adjusting the pressure of the plasma gas inside the chamber.

It should be noted that effects of the disclosure are not limited to those described above and other effects of the disclosure will be apparent to those skilled in the art from the following descriptions.

The sputtering device according to an embodiment may improve plasma density during a manufacturing process by including a protrusion and a depression on a target surface. Accordingly, the sputtering device according to an embodiment may readily form deposition film characteristics required by the display device according to an embodiment.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic cross-sectional view of a sputtering apparatus according to an embodiment;

FIG. 2 is a perspective view of a sputtering apparatus according to an embodiment;

FIG. 3 is a flowchart illustrating a method of forming a deposition layer using the sputtering apparatus according to an embodiment;

FIG. 4 is an enlarged schematic cross-sectional view of a target device in FIG. 1;

FIG. 5 is an enlarged schematic cross-sectional view of area ‘A’ in FIG. 4;

FIG. 6 is a schematic cross-sectional view illustrating the density of plasma gas included in the sputtering apparatus according to an embodiment;

FIG. 7 is a perspective view of a sputtering apparatus according to an embodiment;

FIG. 8 is a schematic cross-sectional view taken along line X1-X1′ of FIG. 7;

FIG. 9 is a perspective view of a display device using a sputtering apparatus according to an embodiment;

FIG. 10 is a schematic cross-sectional view of the display device using the sputtering apparatus according to an embodiment;

FIG. 11 is a plan view illustrating emission areas disposed in a display area in FIG. 10;

FIG. 12 is a schematic cross-sectional view taken along line X2-X2′ of FIG. 11; and

FIG. 13 is an enlarged schematic cross-sectional view of a first emission area in FIG. 12.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. “About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described with reference to the accompanying drawings.

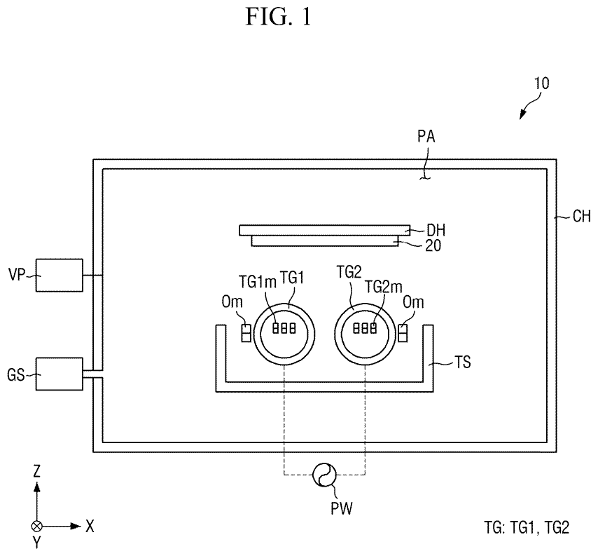

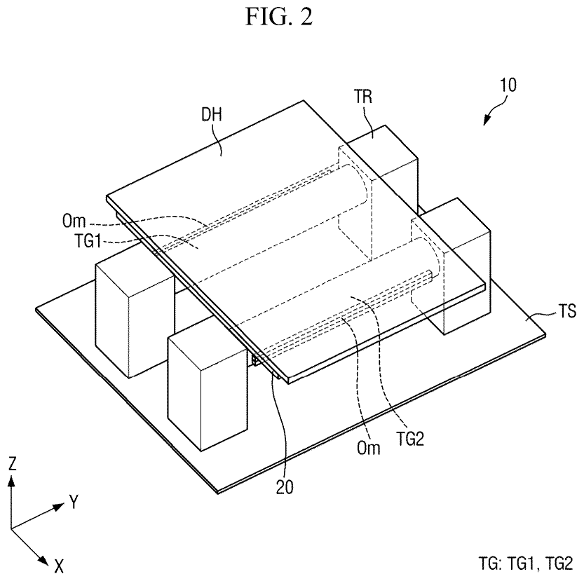

FIG. 1 is a schematic cross-sectional view of a sputtering apparatus 10 according to an embodiment. FIG. 2 is a perspective view of a sputtering apparatus 10 according to an embodiment.

In FIG. 1, a first direction (X-axis direction), a second direction (Y-axis direction), and a third direction (Z-axis direction) are defined. The first direction (X-axis direction) and the second direction (Y-axis direction) may be perpendicular to each other, the first direction (X-axis direction) and the third direction (Z-axis direction) may be perpendicular to each other, and the second direction (Y-axis direction) and the third direction (Z-axis direction) may be perpendicular to each other. In the following specification, unless otherwise specified, a “direction” may refer to both directions extending to both sides along the direction. In addition, when it is necessary to distinguish both “directions” extending to both sides, a side will be referred to as a “first side in the direction,” and another side will be referred to as a “second side in the direction.” Based on FIG. 1, a direction in which an arrow is directed will be referred to as the first side, and a direction opposite to the direction will be referred to as the second side.

Referring to FIGS. 1 and 2, the sputtering apparatus 10 according to an embodiment may include a process chamber CH, a gas supply unit (or gas supply part) GS, a vacuum pump VP, a display holder DH, a target support TS, a voltage device PW, and target rotation devices TR.

The process chamber CH may provide a process space PA. A display device 20 and a target device TG may be placed in the process space PA, and a sputtering deposition process may be performed on the display device 20. The process space PA may be maintained in a vacuum state during a manufacturing process.

The vacuum pump VP may be connected to the process chamber CH. The vacuum pump VP may adjust the vacuum level of the process space PA. For example, the vacuum level of the process space PA in the process chamber CH may be maintained by the vacuum pump VP during a manufacturing process.

The gas supply unit GS may supply plasma gas to the process space PA. The plasma gas supplied from the gas supply unit GS may be sprayed into the process space PA. For example, the plasma gas may be, but is not limited to, argon gas (Ar).

The display holder DH may be spaced apart from the target device TG in the third direction (Z-axis direction). The display holder DH may support the display device 20. The display holder DH may support the display device 20 to prevent the movement or shake of the display device 20 during a deposition process. The display device 20 may be temporarily attached to the display holder DH using magnetism, adsorption, or a physical clamp. The display holder DH may be made of a material with high heat resistance and durability to prevent denaturation and damage due to heat during the deposition process.

In the drawings, the target device TG is located below the display device 20 and the display holder DH in the third direction (Z-axis direction), and the display device 20 and the display holder DH are located above the target device TG in the third direction (Z-axis direction). However, the disclosure is not limited thereto. In another embodiment, the display device 20 and the display holder DH may also be located below the target device TG, and the target device TG may be located above the display device 20 and the display holder DH.

The target support TS may support the target device TG. The target support TS may guide ionized target particles separated from the target device TG to proceed toward the display device 20. The target support TS may be made of a material with high heat resistance and durability to prevent denaturation and damage due to heat during a deposition process.

As illustrated in FIG. 2, the target support TS may support the target rotation devices TR. The target rotation devices TR may be fixed at a position by the target support TS. In other words, the target support TS may support the target device TG by supporting the target rotation devices TR.

The target rotation devices TR may be connected to ends of a first target TG1 and a second target TG2, respectively. The target rotation devices TR may rotate the first target TG1 and the second target TG2, respectively. Each of the target rotation devices TR may include an actuator such as an electric motor or a hydraulic motor. The first target TG1 and the second target TG2 may be rotated about the second direction (Y-axis direction) as a central axis by the target rotation devices TR.

Referring to FIGS. 1 and 2, the target device TG may include the first target TG1 and the second target TG2.

The first target TG1 may be placed to face the display device 20 in the third direction (Z-axis direction). The first target TG1 according to an embodiment may be rotated by a target rotation device TR during a deposition process. For example, the first target TG1 may rotate in place about an axis parallel to the second direction (Y-axis direction). This may increase the efficiency of use of the target by uniformly consuming a target material through rotation.

The first target TG1 may have a hollow cylindrical shape which is long in the second direction (Y-axis direction). A length of the first target TG1 in the second direction (Y-axis direction) may be at least equal to or greater than a width of the display device 20 in the second direction (Y-axis direction).

The first target TG1 may include first magnet members TG1m. The first magnet members TG1m may be located inside the hollow cylinder of the first target TG1. The first magnet members TG1m may not rotate even in case that the first target TG1 rotates. For example, the first magnet members TG1m may not be connected to the first target TG1. Multiple first magnet members TG1m may be formed and may be long in the second direction (Y-axis direction).

The second target TG2 and the first target TG1 may include substantially a same material and characteristics. For example, the second target TG2 may be rotated by a target rotation device TR during a deposition process. The second target TG2 may have a hollow cylindrical shape which is long in the second direction (Y-axis direction). A length of the second target TG2 in the second direction (Y-axis direction) may be at least equal to or greater than the width of the display device 20 in the second direction (Y-axis direction). The second target TG2 may be spaced apart from the first target TG1 in the first direction (X-axis direction). The first target TG1 and the second target TG2 may have a same length and a size.

The second target TG2 may include second magnet members TG2m. The second magnet members TG2m may be located inside the hollow cylinder of the second target TG2. The second magnet members TG2m may not rotate even in case that the second target TG2 rotates. For example, the second magnet members TG2m may not be connected to the second target TG2. Multiple second magnet members TG2m may be formed and may be long in the second direction (Y-axis direction).

The voltage device PW may apply an alternating current (AC) voltage to the first target TG1 and the second target TG2. For example, the voltage device PW may be an AC power source.

External magnet members Om may be placed to face the display device 20 in the third direction (Z-axis direction) and may be spaced apart from the first target TG1 and the second target TG2 in the first direction (X-axis direction). In case that a space between the first target TG1 and the second target TG2 is defined as inside, the external magnet members Om may not be disposed inside the first target TG1 and the second target TG2, but may be disposed outside the first target TG1 and the second target TG2, respectively.

As illustrated in FIG. 2, the external magnet members Om may be long in the second direction (Y-axis direction). For example, the external magnet members Om may extend parallel to the first target TG1 and the second target TG2 in the second direction (Y-axis direction). The external magnet members Om and the first target TG1 and the second target TG2 may have a similar length in the second direction (Y-axis direction) and may be parallel with each other.

Since the sputtering apparatus 10 includes the external magnet members Om, the sputtering apparatus 10 may fundamentally prevent abnormal discharge which may be caused by the first magnet members TG1m and the second magnet members TG2m, thereby increasing deposition efficiency. For example, the external magnet members Om may prevent a non-uniform magnetic field which may be formed by the first magnet members TG1m and the second magnet members TG2m. However, the disclosure is not limited thereto, and in another embodiment, the external magnet members Om may be omitted.

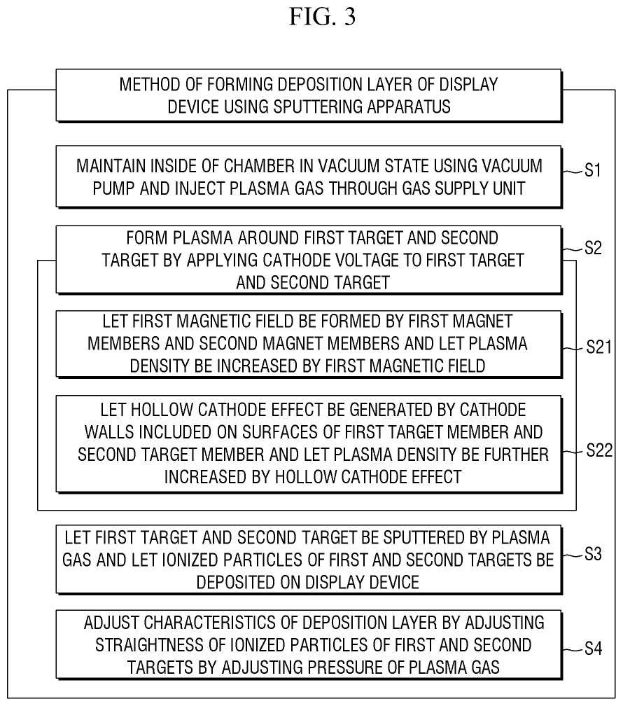

FIG. 3 is a flowchart illustrating a method of forming a deposition layer using the sputtering apparatus 10 according to an embodiment.

Referring to FIG. 3, a method of forming a deposition layer of a display device using the sputtering apparatus 10 according to an embodiment may include a first operation S1 of maintaining the inside of a process chamber in a vacuum state using a vacuum pump and injecting plasma gas through a gas supply unit, a second operation S2 of forming plasma around a first target and a second target by applying a cathode voltage to the first target and the second target, a third operation S3 of letting the first target and the second target be sputtered by the plasma gas and letting ionized particles of the first and second targets be deposited on the display device, and a fourth operation S4 of adjusting the characteristics of the deposition layer by adjusting the straightness of the ionized particles of the first and second targets by adjusting the pressure of the plasma gas inside the chamber.

The second operation S2 may include a first sub-operation S21 of letting a first magnetic field be formed by first magnet members and second magnet members and letting plasma density be increased by the first magnetic field and a second sub-operation S22 of letting a hollow cathode effect be formed by cathode walls included on surfaces of a first target member and a second target member and letting the plasma density be further increased by the hollow cathode effect.

Referring to FIGS. 1 and 2, the sputtering apparatus 10 may perform the first operation S1 by maintaining the inside of the process chamber CH in a vacuum state using the vacuum pump VP and injecting plasma generating gas through the gas supply unit GS.

The sputtering apparatus 10 may apply a cathode voltage to the first target TG1 and the second target TG2 and, although not illustrated, may connect an anode voltage or a ground voltage to a conductor located on an inner wall of the process chamber CH or spaced apart from the first target TG1 and the second target TG2. For example, the second operation S2 may be performed by applying a cathode voltage to the first target TG1 and the second target TG2.

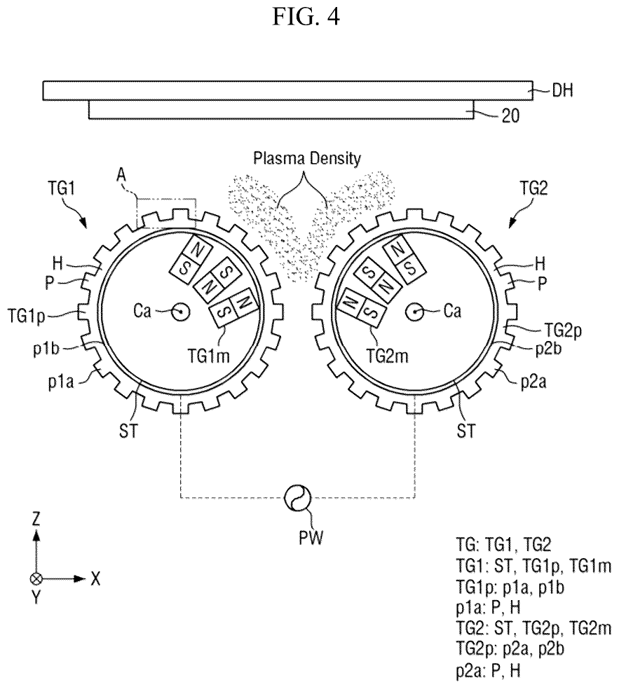

The first sub-operation S21 and the second sub-operation S22 of the second operation S2, the third operation S3, and the fourth operation S4 will now be described with reference to FIGS. 4 through 6.

FIG. 4 is an enlarged schematic cross-sectional view of the target device TG in FIG. 1.

Referring to FIG. 4, the sputtering apparatus 10 may apply an AC voltage to the first target TG1 and the second target TG2 through the voltage device PW. The AC voltage applied to the first target TG1 and the second target TG2 may cause injected plasma gas to be more effectively confined between the first target TG1 and the second target TG2. However, this operation is intended to increase the efficiency of a manufacturing process and may be omitted in another embodiment.

The first sub-operation S21 of letting the first magnetic field be formed by the first magnet members and the second magnet members and letting the plasma density be increased by the first magnetic field will now be described.

The first target TG1 according to an embodiment may include a support target ST, a first target member TG1p, and the first magnet members TG1m. The first target member TG1p will be described below.

The support target ST may support the first target member TG1p. The support target ST may maintain the temperature of the first target member TG1p constant during a deposition process and assist the rotation of the first target member TG1p. A cathode voltage may be applied to the support target ST. Accordingly, the first target member TG1p connected to the support target ST may function as a cathode. In another embodiment, the first target TG1 may be driven without the support target ST, and a cathode voltage may be applied to the first target member TG1p. In an embodiment, the support target ST may be omitted.

The first magnet members TG1m may be located inside the first target member TG1p. Multiple first magnet members TG1m may be formed, and neighboring first magnet members TG1m may be arranged such that different polarities alternate. For example, the first magnet members TG1m may be arranged such that their N pole or S pole face the display device 20 and the second target TG2. In the drawing, three first magnet members TG1m are arranged to face the display device 20, and the N pole, the S pole, and the N pole are alternately arranged facing the display device 20 (and the polarities of the first magnet members TG1m are arranged in the order of the N pole, the S pole, and the N pole in a direction facing the display device 20). However, the disclosure is not limited thereto. For example, the number of first magnet members TG1m may vary, and the polarities of the first magnet members TG1m may be freely arranged.

The first magnet members TG1m may generate a magnetic field around the first magnet members TG1m. For example, the first magnet members TG1m may generate a magnetic field in a direction from the N pole to the S pole. For example, the first magnet members TG1m may generate a magnetic field between the first target member TG1p and the display device 20. Therefore, the sputtering apparatus 10 may readily confine plasma around the first magnet members TG1m by the magnetic field formed by the first magnet members TG1m. For example, in the sputtering apparatus 10, plasma density between the first magnet members TG1m and the display device 20 may increase.

The second target TG2 and the first target TG1 may have a same structure and characteristics. For example, the second target TG2 may include a support target ST, a second target member TG2p, and the second magnet members TG2m. The second target member TG2p will be described below. The support target ST has already been described in the description of the first target TG1, and thus a redundant description thereof will be omitted.

The second magnet members TG2m may be located inside the second target member TG2p. Multiple second magnet members TG2m may be formed, and neighboring second magnet members TG2m may be arranged such that different polarities alternate. For example, the second magnet members TG2m may be arranged such that their N pole or S pole face the display device 20 and the first target TG1. The polarities of the second magnet members TG2m and the first magnet members TG1m face each other may be arranged in a same arrangement. However, the disclosure is not limited thereto. The number of second magnet members TG2m may vary, and the polarities of the second magnet members TG2m may be freely arranged.

The second magnet members TG2m may generate a magnetic field around the second magnet members TG2m. For example, the second magnet members TG2m may generate a magnetic field in a direction from the N pole to the S pole. For example, the second magnet members TG2m may generate a magnetic field between the second target member TG2p and the display device 20. Therefore, the sputtering apparatus 10 may readily confine plasma around the second magnet members TG2m by the magnetic field formed by the second magnet members TG2m. For example, in the sputtering apparatus 10, plasma density between the second magnet members TG2m and the display device 20 may increase.

In some embodiments, the plasma gas confined by the first magnet members TG1m and the plasma gas confined by the second magnet members TG2m may partially overlap. Accordingly, the first sub-operation S21 may be performed.

The second sub-operation S22 of letting the hollow cathode effect be formed by the cathode walls included on the surfaces of the first target member and the second target member and letting the plasma density be further increased by the hollow cathode effect will be described.

The first target member TG1p according to an embodiment may be located on the support target ST. The first target member TG1p may rotate about a cylindrical axis Ca. The first target member TG1p may include a metal material to be deposited on the display device 20. For example, the first target member TG1p may include at least one of ytterbium (Yb), aluminum (Al), magnesium (Mg), silver (Ag), lithium (Li), platinum (Pt), palladium (Pd), nickel (Ni), gold (Au), neodymium (Nd), iridium (Ir), chromium (Cr), and barium (Ba).

In some embodiments, the first target member TG1p may include a first surface p1a facing outward toward the display device 20 or the display holder DH and a second surface p1b opposite the first surface p1a and facing the support target ST.

The first surface p1a according to an embodiment may include protrusions P and hollows H which are repeated. For example, the first surface p1a according to an embodiment may be shaped like a cogwheel and may completely surround the support target ST. The second surface p1b according to an embodiment may not include the protrusions P and the hollows H and may contact the support target ST.

The second target member TG2p according to an embodiment may be located on the support target ST. The second target member TG2p may rotate about a cylindrical axis Ca. The second target member TG2p may include a material to be deposited on the display device 20. For example, the second target member TG2p may include at least one of ytterbium (Yb), aluminum (Al), magnesium (Mg), silver (Ag), lithium (Li), platinum (Pt), palladium (Pd), nickel (Ni), gold (Au), neodymium (Nd), iridium (Ir), chromium (Cr), and barium (Ba).

In some embodiments, the second target member TG2p may include a first surface p2a facing outward toward the display device 20 or the display holder DH and a second surface p2b opposite the first surface p2a and facing the support target ST.

The first surface p2a according to an embodiment may include protrusions P and hollows H that are repeated. For example, the first surface p2a according to an embodiment may be shaped like a cogwheel and may completely surround the support target ST. The second surface p2b according to an embodiment may not include the protrusions P and the hollows H and may contact the support target ST.

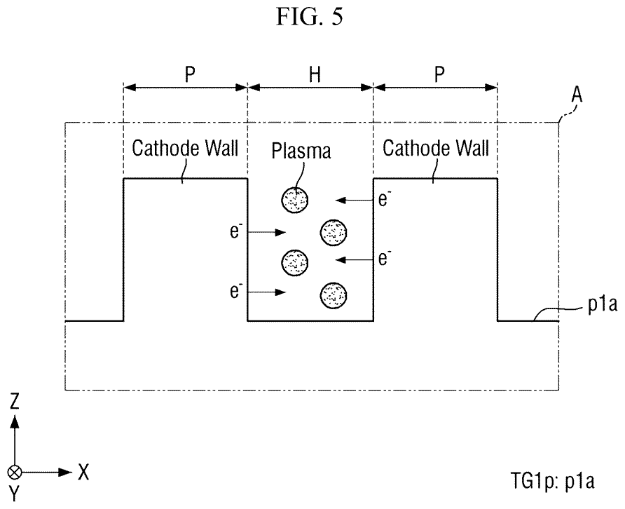

FIG. 5 is an enlarged schematic cross-sectional view of area ‘A’ in FIG. 4.

Referring to FIG. 5, the first surface p1a according to an embodiment may have a structure in which the protrusions P and the hollows H are alternately repeated. Accordingly, cathode walls may be formed in portions of the protrusions P. For example, the sputtering apparatus 10 according to an embodiment may perform a deposition process by applying a cathode voltage to the first target TG1. Accordingly, the inside of the cathode walls of the first target member TG1p may be filled with the cathode voltage. However, the disclosure is not limited thereto, and in another embodiment, the cathode walls may be formed in a cylindrical shape.

The cathode walls may neighbor each other in a circumferential direction of the target device TG. Accordingly, a hollow cathode effect may be formed between the cathode walls spaced apart from each other. The hollow cathode effect refers to a large increase in current density between neighboring cathode walls due to a reduced distance between the cathode walls in case that cathodes having the same electric potential face each other in the form of walls.

In other words, electrons (e−) formed in the cathode walls having high energy may be emitted from the cathode walls and may be vibrated and accelerated by a repulsive potential difference between the cathode walls corresponding to each other. The electrons (e−) having the accelerated energy may countlessly collide with plasma gas particles in their movement path, thereby forming high plasma density between the cathode walls. Accordingly, the sputtering apparatus 10 may perform the second sub-operation S22.

The second target member TG2p included in the second target TG2 and the first target member TG1p may have a same structure and characteristics, and thus a redundant description thereof will be omitted.

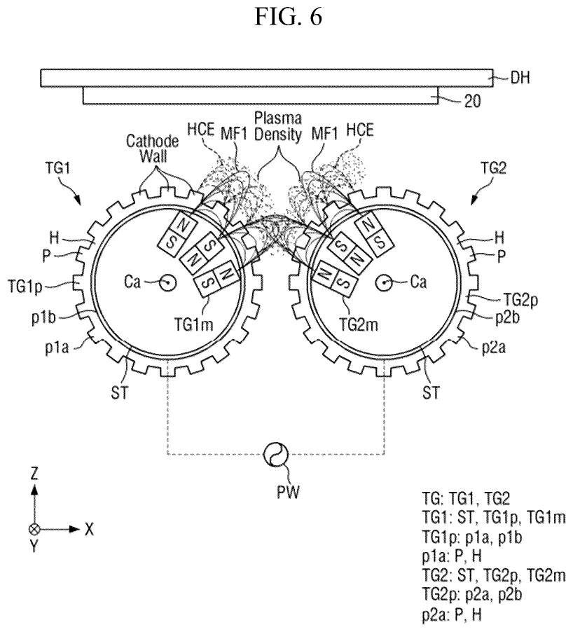

FIG. 6 is a schematic cross-sectional view illustrating the density of plasma gas included in the sputtering apparatus 10 according to an embodiment.

Referring to FIG. 6, as described above, the sputtering apparatus 10 according to an embodiment including the first magnet members TG1m and the second magnet members TG2m may form a first magnetic field, and the first magnetic field may be in the form of first magnetic field lines MF1. For example, the first magnetic field may be connected from the N pole to the S pole included in the first magnet members TG1m and the second magnet members TG2m.

In the sputtering apparatus 10, each of the first target member TG1p and the second target member TG2P may include multiple cathode walls spaced apart from each other on an outer surface of the target device TG. Accordingly, a hollow cathode effect may be formed, and the density of plasma gas in a space between the display device 20 and the first and second targets TG1 and TG2 may be increased by the hollow cathode effect. In other words, the hollow cathode effect may be formed between neighboring cathode walls. For example, in the sputtering apparatus 10, plasma gas may be more readily confined in an area between a portion where the first magnetic field lines MF1 are formed and a portion where the hollow cathode effect is formed.

The third operation S3 following the second sub-operation S22 will now be described.

In the sputtering apparatus 10, the sputtering of the first target TG1 and the second target TG2 may be readily performed due to the increased plasma density, and ionized particles of the first and second targets TG1 and TG2 may be deposited on the display device 20. In the third operation S3, the sputtering apparatus 10 according to an embodiment may form high plasma density even under low-voltage conditions. Therefore, it may be possible to form a deposition layer with high thin-film density and avoid damage to the display device 20 caused by a voltage. A metal deposition layer with high thin-film density may support excellent electrical characteristics of the display device 20.

The fourth operation S4 of adjusting the characteristics of the deposition layer deposited on the display device by adjusting the straightness of the ionized particles of the first and second targets TG1 and TG2 by adjusting the pressure of the plasma gas may be performed after the third operation S3.

The sputtering apparatus 10 may perform a deposition process at a high vacuum level. For example, the vacuum level of the sputtering apparatus 10 according to an embodiment may be greater than or equal to about 3×10⁴ torr. Therefore, the ionized particles of the first target TG1 and the second target TG2 in an embodiment may be deposited on the display device 20 with high straightness. The sputtering apparatus 10 may control the straightness and directionality of the target particles by adjusting the pressure of the plasma gas according to an embodiment. Therefore, a deposition layer formed using the sputtering apparatus 10 may be readily manufactured according to the characteristics required by the display device 20. For example, a deposition layer formed using the sputtering apparatus 10 may be deposited on the display device 20 as a cathode.

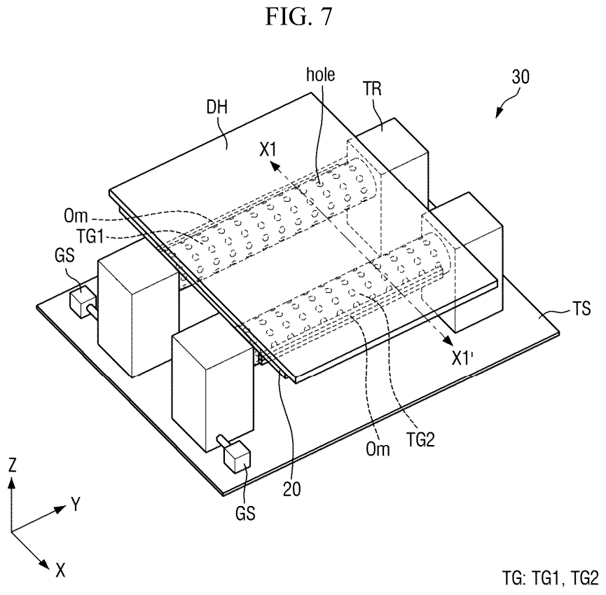

FIG. 7 is a perspective view of a sputtering apparatus 30 according to an embodiment.

Referring to FIG. 7, target rotation devices TR and gas supply units GS may be disposed on a target support TS in an embodiment. The sputtering apparatus 30 in FIG. 3 may be different from the sputtering apparatus 10 of FIG. 2 in that the gas supply units GS penetrate into the target rotation devices TR and inject gas into a target device TG. However, the disclosure is not limited thereto, and the gas supply units GS may also be connected (e.g., directly connected) to the target device TG in another embodiment.

A first target TG1 and a second target TG2 according to an embodiment may include holes on surfaces. Multiple holes may be formed to surround a long cylinder. In the sputtering apparatus 30 according to an embodiment, plasma gas may be injected into the first target TG1 and the second target TG2 through the gas supply units GS and may be supplied through the holes formed on the surfaces of the first target TG1 and the second target TG2. Particles of the first target TG1 and the second target TG2 ionized by the plasma gas may be deposited on a display device 20 mounted on a display holder DH. External magnet members Om have already been described above, and thus a description thereof will be omitted. Other redundant descriptions will be omitted.

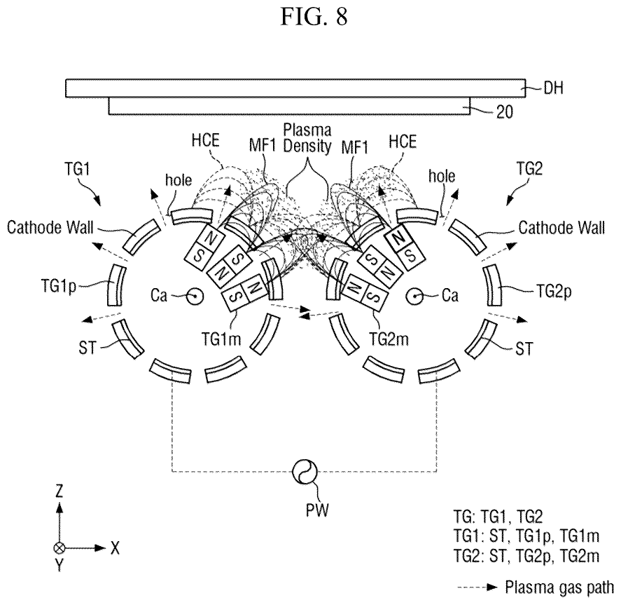

FIG. 8 is a schematic cross-sectional view taken along line X1-X1′ of FIG. 7. FIG. 8 is a schematic cross-sectional view taken through the holes of the first target TG1 and the second target TG2 in FIG. 7.

Referring to FIG. 8, the first target TG1 according to an embodiment may include a support target ST, a first target member TG1p, and first magnet members TG1m. The first target TG1 according to an embodiment may include holes penetrating the support target ST and the first target member TG1p. The holes may be spaced apart from each other, and plasma gas injected into the first target TG1 may be released through the holes along plasma gas paths illustrated in the drawing. Although the plasma gas paths are formed in a direction toward the display device 20 in the drawing, the disclosure is not limited thereto. In another embodiment, the plasma gas may be released in any direction through portions where the holes are formed.

The support target ST according to an embodiment may be provided to support the first target member TG1p. The support target ST may maintain the temperature of the first target member TG1p constant during a deposition process. A cathode voltage may be applied to the support target ST. Accordingly, the first target member TG1p connected to the support target ST may function as a cathode. In another embodiment, the first target TG1 may be driven without the support target ST, and a cathode voltage may be applied to the first target member TG1p. A redundant description of the first magnet members TG1m will be omitted.

The second target TG2 and the first target TG1 may have a same structure and characteristics. For example, the second target TG2 may include a support target ST, a second target member TG2p, and second magnet members TG2m. The second target TG2 according to an embodiment may include holes penetrating the support target ST and the second target member TG2p, and plasma gas injected into the second target TG2 through the holes may be released through plasma gas paths illustrated in the drawing. A redundant description of the second magnet members TG2m will be omitted.

The first target member TG1p according to an embodiment may be located on the support target ST and may rotate about a cylindrical axis Ca. The first target member TG1p may include a material to be deposited on the display device 20.

In the cross-sectional view, the first target member TG1p may have multiple walls facing each other with a hole between the first target members TG1p. As described above, the sputtering apparatus 30 may perform a deposition process by applying a cathode voltage to the first target TG1, and accordingly, the inside of the first target TG1 may be filled with the cathode voltage. Therefore, the first target member TG1p may have cathode walls neighboring each other with a hole between the first target members TG1p. However, the disclosure is not limited thereto, and in another embodiment, the cathode walls may be formed in a cylindrical shape. Since the cathode walls have already been described, a description thereof will be omitted.

The second target member TG2p included in the second target TG2 and the first target member TG1p may include a same structure and characteristics, and thus a redundant description thereof will be omitted.

The sputtering apparatus 30 including the first magnet members TG1m and the second magnet members TG2m may form a first magnetic field, and the first magnetic field may be in the form of first magnetic field lines MF1. For example, the first magnetic field may be connected from the N pole to the S pole included in the first magnet members TG1m and the second magnet members TG2m.

In the sputtering apparatus 30 according to an embodiment, each of the first target member TG1p and the second target member TG2P may include multiple cathode walls spaced apart from each other with a hole between each of the first target members TG1p and the second target members TG2P. Accordingly, a hollow cathode effect may be formed between neighboring cathode walls. For example, the hollow cathode effect may be formed between neighboring cathode walls in a form illustrated in the drawing. Plasma gas may be confined to a higher density in a space in which the hollow cathode effect is formed. In other words, in the sputtering apparatus 30, a portion where the first magnetic field lines MF1 are formed and a portion where the hollow cathode effect is formed may overlap, and plasma gas may be more readily confined in the overlapping portion. Therefore, plasma density between the display device 20 and the target device TG may increase.

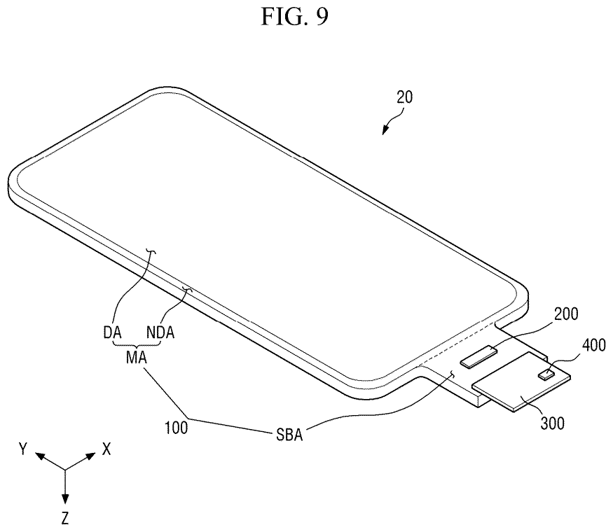

FIG. 9 is a perspective view of a display device 20 according to an embodiment. FIG. 9 is a perspective view of the display device 20 formed using the sputtering apparatus 10 and the sputtering apparatus 30 according to embodiments.

Referring to FIG. 9, the display device 20 according to an embodiment may provide a screen. The display device 20 may be, for example, an inorganic light emitting diode display device, an organic light emitting display device, a quantum dot light emitting display device, a plasma display panel, or a field emission display device. An organic light emitting diode display device is applied as an embodiment of the display device 20 will be described below, but the disclosure is not limited thereto, and other display devices may also be applied as long as the same technical spirit is applicable.

The display device 20 may have a shape similar to a rectangle in a plan view having short sides in the first direction (X-axis direction) and long sides in the second direction (Y-axis direction). Each corner where a short side extending in the first direction (X-axis direction) meets a long side extending in the second direction (Y-axis direction) may be rounded with a curvature. However, the disclosure is not limited thereto, and each corner may be right-angled. The planar shape of the display device 20 is not limited to a quadrilateral shape but may be similar to other polygonal shapes, a circular shape, or an oval shape.

The display device 20 may include a display panel 100, a display driver 200, a circuit board 300, and a touch driver 400.

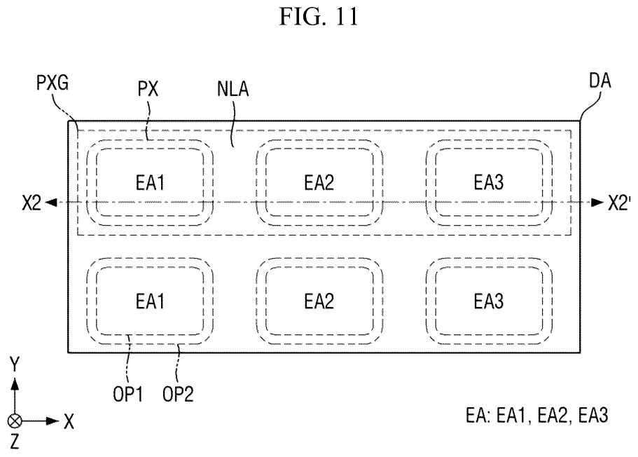

The display panel 100 may include a main area MA and a sub-area SBA. The main area MA may include a display area DA including pixels PX (see FIG. 11) that displays an image and a non-display area NDA disposed adjacent to the display area DA.

The display area DA may emit light from multiple emission areas or multiple openings which will be described below. The non-display area NDA may be an area adjacent to the display area DA. The non-display area NDA may be defined as an edge area of the display area DA of the display panel 100.

The sub-area SBA may be an area extending from a side of the main area MA. The sub-area SBA may include a flexible material that can be bent, folded, rolled, etc. For example, in case that the sub-area SBA is bent, the sub-area SBA may overlap the main area MA in a thickness direction (third direction (Z-axis direction)). In an embodiment, the sub-area SBA may be omitted, and the display driver 200 and a pad unit may be located in the non-display area NDA.

The display driver 200 may output signals and voltages for driving the display panel 100. The display driver 200 may be formed as an integrated circuit and mounted on the display panel 100 using a chip on glass (COG) method, a chip on plastic (COP) method, or an ultrasonic bonding method. For example, the display driver 200 may be disposed in the sub-area SBA and may overlap the main area MA in the thickness direction by the bending of the sub-area SBA. In another embodiment, the display driver 200 may be mounted on the circuit board 300.

The circuit board 300 may be attached onto the pad unit of the display panel 100 using an anisotropic conductive film. The circuit board 300 may be a flexible printed circuit board, a printed circuit board, or a flexible film such as a chip on film.

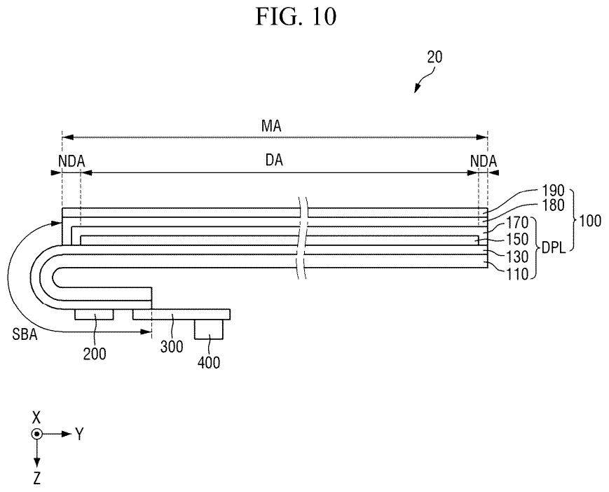

The touch driver 400 may be mounted on the circuit board 300. The touch driver 400 may be connected to a touch senor layer 180 (see FIG. 10) of the display panel 100. The touch driver 400 may be formed as an integrated circuit.

FIG. 10 is a schematic cross-sectional view of the display device 20 according to an embodiment.

Referring to FIG. 10, the display panel 100 may include a display layer DPL, the touch sensor layer 180, and a color filter layer 190. The display layer DPL may include a substrate 110, a thin-film transistor layer 130, a display element layer 150, and a thin-film encapsulation layer 170.

The substrate 110 may be a base substrate or a base member. The substrate 110 may be a flexible substrate that can be bent, folded, rolled, etc. For example, the substrate 110 may include a polymer resin including polyimide (PI). However, the disclosure is not limited thereto. In an embodiment, the substrate 110 may include a glass material or a metal material.

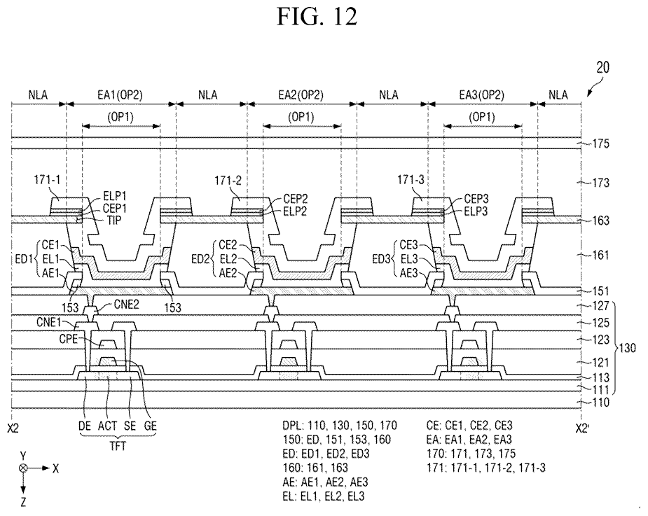

The thin-film transistor layer 130 may be disposed on the substrate 110. The thin-film transistor layer 130 may be disposed in the display area DA, the non-display area NDA, and the sub-area SBA. The thin-film transistor layer 130 may include multiple thin-film transistors TFT (see FIG. 12) constituting pixels PX (see FIG. 11).

The display element layer 150 may be disposed on the thin-film transistor layer 130. The display element layer 150 may be disposed in the display area DA. The display element layer 150 may include multiple light emitting elements ED (see FIG. 12). For example, each of the light emitting elements ED according to an embodiment may include, but is not limited to, at least one of an organic light emitting diode including an organic light emitting layer, a quantum dot light emitting diode including a quantum dot light emitting layer, an inorganic light emitting diode including an inorganic semiconductor, and a micro-light emitting diode.

The thin-film encapsulation layer 170 may be located on the display element layer 150. The thin-film encapsulation layer 170 may be disposed in the display area DA and the non-display area NDA. The thin-film encapsulation layer 170 may cover upper and side surfaces of the display element layer 150 and may protect the display element layer 150 from external oxygen and moisture. The thin-film encapsulation layer 170 may include at least one inorganic layer and at least one organic layer to encapsulate the display element layer 150.

The touch sensor layer 180 may be disposed on the thin-film encapsulation layer 170. The touch sensor layer 180 may be disposed in the display area DA and the non-display area NDA. The touch sensor layer 180 may sense a user's touch using a mutual capacitance method or a self-capacitance method.

The color filter layer 190 may be disposed on the touch sensor layer 180. The color filter layer 190 may be disposed in the display area DA and the non-display area NDA. The color filter layer 190 may reduce reflected light caused by external light by absorbing some of the light incident from the outside of the display device 20. Therefore, the color filter layer 190 may prevent color distortion caused by the reflection of external light.

Since the color filter layer 190 is disposed (e.g., directly disposed) on the touch sensor layer 180, the display device 20 may not require a separate substrate for the color filter layer 190. Therefore, a thickness of the display device 20 may be relatively small. The color filter layer 190 may be omitted in another embodiment.

As illustrated in FIG. 10, a portion of the display layer DPL which overlaps the sub-area SBA may be bent. In case that a portion of the display layer DPL is bent, the display driver 200, the circuit board 300, and the touch driver 400 may overlap the main area MA in the third direction (Z-axis direction).

FIG. 11 is a plan view illustrating emission areas EA disposed in the display area DA in FIG. 10.

Referring to FIG. 11, the display area DA according to an embodiment may include first through third emission areas EA1 through EA3 and a non-emission area NLA. The non-emission area NLA may surround the first through third emission areas EA1 through EA3 in a plan view.

The non-emission area NLA may block light emitted from each of the first through third emission areas EA1 through EA3. Therefore, the non-emission area NLA may prevent the color mixing of light emitted from the first through third emission areas EA1 through EA3. A pixel defining layer 151 (see FIG. 12) and a bank structure 160 (see FIG. 12) which will be described below may be disposed in the non-emission area NLA.

The emission areas EA may include first emission areas EA1, second emission areas EA2, and third emission areas EA3 that emit light of different colors. Each of the first through third emission areas EA1 through EA3 may emit red light, green light, or blue light. The color of light emitted from each of the first through third emission areas EA1 through EA3 may vary according to the type of light emitting element ED which will be described below. For example, the first emission areas EA1 may emit red light, i.e., light of a first color, the second emission areas EA2 may emit green light, i.e., light of a second color, and the third emission areas EA3 may emit blue light, i.e., light of a third color, but the disclosure is not limited thereto. Although the first through third emission areas EA1 through EA3 have the same size and shape in the drawing, the disclosure is not limited thereto. The size and shape of each of the first through third emission areas EA1 through EA3 may be adjusted according to required characteristics.

The first through third emission areas EA1 through EA3 may be defined by first openings OP1 and second openings OP2. For example, the first openings OP1 may be defined by the pixel defining layer 151 (see FIG. 12) which will be described below, and the second openings OP2 may be defined by the bank structure 160 (see FIG. 12) which will be described below. The second openings OP2 may completely surround the first openings OP1 in a plan view. The second openings OP2 may be completely surrounded by the non-emission area NLA in a plan view.

In some embodiments, at least one first emission area EA1, at least one second emission area EA2, and at least one third emission area EA3 disposed adjacent to each other may form one pixel group PXG. The pixel group PXG may be a smallest unit that emits white light. However, the types and/or number of the first through third emission areas EA1 through EA3 constituting the pixel group PXG may vary according to embodiments.

FIG. 12 is a schematic cross-sectional view taken along line X2-X2′ of FIG. 11. FIG. 12 schematically illustrates a cross section of the display layer DPL in the display area DA. For example, FIG. 12 schematically illustrates cross sections of the substrate 110, the thin-film transistor layer 130, the display element layer 150, and the thin-film encapsulation layer 170. Since the substrate 110 has already been described, a redundant description thereof will be omitted.

Referring to FIG. 12, the thin-film transistor layer 130 may be located on the substrate 110. The thin-film transistor layer 130 may include a first buffer layer 111, thin-film transistors TFT, a gate insulating layer 113, a first interlayer insulating layer 121, capacitor electrodes CPE, a second interlayer insulating layer 123, first connection electrodes CNE1, a first via layer 125, second connection electrodes CNE2, and a second via layer 127.

The first buffer layer 111 may be disposed on the substrate 110. The first buffer layer 111 may include an inorganic layer that can prevent the penetration of air or moisture. For example, the first buffer layer 111 may include multiple inorganic layers stacked alternately.

The thin-film transistors TFT may be disposed on the first buffer layer 111 and may constitute pixel circuits respectively connected to multiple pixels. For example, each of the thin-film transistors TFT may be a driving transistor or a switching transistor of a pixel circuit. Each of the thin-film transistors TFT may include an active layer ACT, a source electrode SE, a drain electrode DE, and a gate electrode GE.

The active layer ACT may be disposed on the first buffer layer 111. The active layer ACT may overlap the gate electrode GE in the third direction (Z-axis direction) and may be insulated from the gate electrode GE by the gate insulating layer 113. The material of the active layer ACT may be made conductive in portions of the active layer ACT to form the source electrode SE and the drain electrode DE.

The gate electrode GE may be disposed on the gate insulating layer 113. The gate electrode GE may overlap the active layer ACT in a plan view, and the gate insulating layer 113 may be interposed between the gate electrode GE and the active layer ACT.

The gate insulating layer 113 may be disposed on the active layers ACT. The gate insulating layer 113 may cover the active layers ACT and the first buffer layer 111 and may insulate the active layers ACT from the gate electrodes GE. The gate insulating layer 113 may include contact holes through which the first connection electrodes CNE1 pass.

The first interlayer insulating layer 121 may cover the gate electrodes GE and the gate insulating layer 113. The first interlayer insulating layer 121 may include contact holes through which the first connection electrodes CNE1 pass. The contact holes of the first interlayer insulating layer 121 may be connected to the contact holes of the gate insulating layer 113 and contact holes of the second interlayer insulating layer 123.

The capacitor electrodes CPE may be disposed on the first interlayer insulating layer 121. The capacitor electrodes CPE may overlap the gate electrodes GE in the third direction (Z-axis direction). The capacitor electrodes CPE and the gate electrodes GE may form capacitance.

The second interlayer insulating layer 123 may cover the capacitor electrodes CPE and the first interlayer insulating layer 121. The second interlayer insulating layer 123 may include contact holes through which the first connection electrodes CNE1 pass. The contact holes of the second interlayer insulating layer 123 may be connected to the contact holes of the first interlayer insulating layer 121 and the contact holes of the gate insulating layer 113.

The first connection electrodes CNE1 may be disposed on the second interlayer insulating layer 123. The first connection electrodes CNE1 may electrically connect the drain electrodes DE of the thin-film transistors TFT to the second connection electrodes CNE2. The first connection electrodes CNE1 may be inserted into the contact holes formed in the first interlayer insulating layer 121, the second interlayer insulating layer 123, and the gate insulating layer 113 and contact the drain electrodes DE of the thin-film transistors TFT.

The first via layer 125 may cover the first connection electrodes CNE1 and the second interlayer insulating layer 123. The first via layer 125 may planarize structures under the first via layer 125. The first via layer 125 may include contact holes through which the second connection electrodes CNE2 pass.

The second connection electrodes CNE2 may be disposed on the first via layer 125. The second connection electrodes CNE2 may be inserted into the contact holes formed in the first via layer 125 and contact the first connection electrodes CNE1. The second connection electrodes CNE2 may electrically connect the first connection electrodes CNE1 to anodes AE.

The second via layer 127 may cover the second connection electrodes CNE2 and the first via layer 125. The second via layer 127 may include contact holes through which the anodes AE pass.

The display element layer 150 may be disposed on the thin-film transistor layer 130. The display element layer 150 may include the light emitting elements ED, the pixel defining layer 151, residual patterns 153, and the bank structure 160.

Each of the light emitting elements ED may include an anode AE, a light emitting layer EL, and a cathode CE. The light emitting elements ED may include a first light emitting element ED1 disposed in a first emission area EA1, a second light emitting element ED2 disposed in a second emission area EA2, and a third light emitting element ED3 disposed in a third emission area EA3.

The first through third light emitting elements ED1 through ED3 may emit light of different colors depending on the materials of first through third light emitting layers EL1 through EL3. For example, the first light emitting element ED1 may emit red light of the first color, the second light emitting element ED2 may emit green light of the second color, and the third light emitting element ED3 may emit blue light of the third color.

The anodes AE may be disposed on the second via layer 127. The anodes AE may be electrically connected to the drain electrodes DE of the thin-film transistors TFT through the first connection electrodes CNE1 and the second connection electrodes CNE2.

The anodes AE may include a first anode AE1 disposed in the first emission area EA1, a second anode AE2 disposed in the second emission area EA2, and a third anode AE3 disposed in the third emission area EA3. The first anode AE1, the second anode AE2, and the third anode AE3 may be spaced apart from each other on the second via layer 127.

In an embodiment, the anodes AE may have a stacked structure of a material layer having a high work function such as indium-tin-oxide (ITO), indium-zinc-oxide (IZO), zinc oxide (ZnO) or indium oxide (In₂O₃) and a reflective material layer such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), or a mixture thereof. For example, the anodes AE may have, but are not limited to, a multilayer structure of ITO/Mg, ITO/MgF, ITO/Ag, or ITO/Ag/ITO.

The pixel defining layer 151 may be disposed on the second via layer 127 and the anodes AE. As described above, the pixel defining layer 151 may define the first openings OP1 that form the emission areas EA. The pixel defining layer 151 may be disposed on the second via layer 127, and may partially expose upper surfaces of the anodes AE. For example, the pixel defining layer 151 may expose the anodes AE in portions overlapping the first openings OP1 in a plan view, and the light emitting layers EL may be disposed (e.g., directly disposed) on the anodes AE in the portions overlapping the first openings OP1 in a plan view.

The pixel defining layer 151 may include an inorganic insulating material. For example, the pixel defining layer 151 may include aluminum oxide, titanium oxide, tantalum oxide, hafnium oxide, zinc oxide, silicon oxide, silicon nitride, silicon oxynitride, or a combination thereof.

The bank structure 160 may be disposed on the pixel defining layer 151. The bank structure 160 may define the second openings OP2 that form the emission areas EA, and the light emitting elements ED of the display device 20 may overlap the second openings OP2 in a plan view. The bank structure 160 may include a first bank layer 161 and a second bank layer 163 including different metal materials and structures to play different roles. The bank structure 160 will be described below.

The light emitting layers EL may be disposed on the anodes AE. Each of the light emitting layers EL may be an organic light emitting layer made of an organic material and may be formed on an anode AE through a deposition process. In case that a thin-film transistor TFT applies a voltage to an anode AE and a cathode CE receives a common voltage or a cathode voltage, holes and electrons may move to a light emitting layer EL through a hole transport layer and an electron transport layer, respectively, and may be combined with each other in the light emitting layer EL to emit light.

The light emitting layers EL may include a first light emitting layer EL1, a second light emitting layer EL2, and a third light emitting layer EL3 disposed in the first through third emission areas EA1 through EA3, respectively. For example, the first light emitting layer EL1 may emit red light of the first color, the second light emitting layer EL2 may emit green light of the second color, and the third light emitting layer EL3 may emit blue light of the third color, but the disclosure is not limited thereto.

In some embodiments, the anodes AE may be spaced apart from the pixel defining layer 151 in the third direction (Z-axis direction). The light emitting layers EL and the residual patterns 153 may be disposed between the anodes AE and the pixel defining layer 151 spaced apart from each other. The residual patterns 153 may be residues of a temporary protective layer which is temporarily formed on the anodes AE during a process of manufacturing the display device 20 and removed.

The cathodes CE may be disposed on the light emitting layers EL. The cathodes CE may be formed by the sputtering apparatus 10 or the sputtering apparatus 30. The cathodes CE and the first target TG1 and the second target TG2 may have a same material.

The cathodes CE may include a transparent conductive material to transmit light generated from the light emitting layers EL. The cathodes CE may receive a common voltage or a low-potential voltage. In case that an anode AE receives a voltage corresponding to a data voltage and a cathode CE receives a low-potential voltage, a potential difference may be formed between the anode AE and the cathode CE. Accordingly, a light emitting layer EL may emit light.

In an embodiment, the cathodes CE may include a material layer having a small work function such as Li, Ca, LiF/Ca, LiF/Al, Al, Mg, Ag, Pt, Pd, Ni, Au Nd, Ir, Cr, BaF, Ba, or a compound or mixture thereof (e.g., a mixture of Ag and Mg). The cathodes CE may further include a transparent metal oxide layer disposed on the material layer having a small work function.

The cathodes CE may include a first cathode CE1, a second cathode CE2, and a third cathode CE3 disposed in the first through third emission areas EA1 through EA3, respectively. The first cathode CE1 may be disposed on the first light emitting layer EL1 in the first emission area EA1, the second cathode CE2 may be disposed on the second light emitting layer EL2 in the second emission area EA2, and the third cathode CE3 may be disposed on the third light emitting layer EL3 in the third emission area EA3.

The first cathode CE1, the second cathode CE2, and the third cathode CE3 may be spaced apart from each other. The cathodes CE may not be directly connected but may be electrically connected through the first bank layer 161 of the bank structure 160.

First through third organic patterns ELP1 through ELP3 and first through third electrode patterns CEP1 through CEP3 may be disposed on the bank structure 160 and surround the first openings OP1 in a plan view.

The first through third organic patterns ELP1 through ELP3 may be located on the second bank layer 163. The first through third organic patterns ELP1 through ELP3 and the first through third light emitting layers EL1 through EL3, respectively may include a same material. The first organic pattern ELP1 and the first light emitting layer EL1 may include a same material, the second organic pattern ELP2 and the second light emitting layer EL2 may include a same material, and the third organic pattern ELP3 and the third light emitting layer EL3 may include a same material. The first through third organic patterns ELP1 through ELP3 may be traces formed as they are separated from the first through third light emitting layers EL1 through EL3 by tips TIP included in the bank structure 160.

The first through third electrode patterns CEP1 through CEP3 may be disposed on the first through third organic patterns ELP1 through ELP3. The arrangement relationship between the first through third electrode patterns CEP1 through CEP3 and the first through third organic patterns ELP1 through ELP3 and the arrangement relationship between the first through third light emitting layers EL1 through EL3 and the first through third cathodes CE1 through CE3 may be the same. The first through third electrode patterns CEP1 through CEP3 and the first through third cathodes CE1 through CE3 may include a same material. The first through third electrode patterns CEP1 through CEP3 may be traces formed as they are separated from the first through third cathodes CE1 through CE3 by the tips TIP included in the bank structure 160.

The thin-film encapsulation layer 170 may be disposed on the display element layer 150. The thin-film encapsulation layer 170 may include at least one inorganic layer to prevent the penetration of oxygen or moisture into the display element layer 150. The thin-film encapsulation layer 170 may include at least one organic layer to protect the display element layer 150 from foreign substances such as dust.

In an embodiment, the thin-film encapsulation layer 170 may include a first encapsulation layer 171, a second encapsulation layer 173, and a third encapsulation layer 175 stacked sequentially. The first encapsulation layer 171 and the third encapsulation layer 175 may be inorganic encapsulation layers, and the second encapsulation layer 173 disposed between the first encapsulation layer 171 and the third encapsulation layer 175 may be an organic encapsulation layer.

The first encapsulation layer 171 may include first through third inorganic layers 171-1 through 171-3. The first through third inorganic layers 171-1 through 171-3 may cover the light emitting elements ED and the bank structure 160. Since the first through third inorganic layers 171-1 through 171-3 can be formed through a chemical vapor deposition (CVD) process, the first through third inorganic layers 171-1 through 171-3 may be formed to a uniform thickness along the profiles of structures under the first through third inorganic layers 171-1 through 171-3.

The first through third inorganic layers 171-1 through 171-3 may overlap the first through third emission areas EA1 through EA3 in a plan view, respectively. For example, the first inorganic layer 171-1 may overlap the first emission area EA1 to cover the first cathode CE1 and the first electrode pattern CEP1, the second inorganic layer 171-2 may overlap the second emission area EA2 to cover the second cathode CE2 and the second electrode pattern CEP2, and the third inorganic layer 171-3 may overlap the third emission area EA3 to cover the third cathode CE3 and the third electrode pattern CEP3 in a plan view. The first through third inorganic layers 171-1 through 171-3 may overlap the non-emissive area NLA to expose the bank structure 160 in a plan view and may be spaced apart from each other.

Although the first through third inorganic layers 171-1 through 171-3 are formed on the same layer in the drawing, the first through third inorganic layers 171-1 through 171-3 may be formed in different processes. For example, the first inorganic layer 171-1 may be formed after the first cathode CE1 is formed, the second inorganic layer 171-2 may be formed after the second cathode CE2 is formed, and the third inorganic layer 171-3 may be formed after the third cathode CE3 is formed.

The first encapsulation layer 171 may include an inorganic insulating material. The first encapsulation layer 171 may include at least one of aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), and silicon oxynitride (Si₂N₂O).

The second encapsulation layer 173 may be located on the first encapsulation layer 171. The second encapsulation layer 173 may flatten steps formed by the first encapsulation layer 171.

The second encapsulation layer 173 may include a polymer-based material. For example, the second encapsulation layer 173 may include at least one of an acrylic resin, an epoxy resin, polyimide, and polyethylene. For example, the second encapsulation layer 173 may include an acrylic resin such as polymethyl methacrylate or polyacrylic acid. The second encapsulation layer 173 may be formed by curing a monomer or applying a polymer.

The third encapsulation layer 175 may be disposed on the second encapsulation layer 173. The third encapsulation layer 175 and the first encapsulation layer 171 may include a same material. The third encapsulation layer 175 may prevent the penetration of oxygen or moisture into the second encapsulation layer 173.

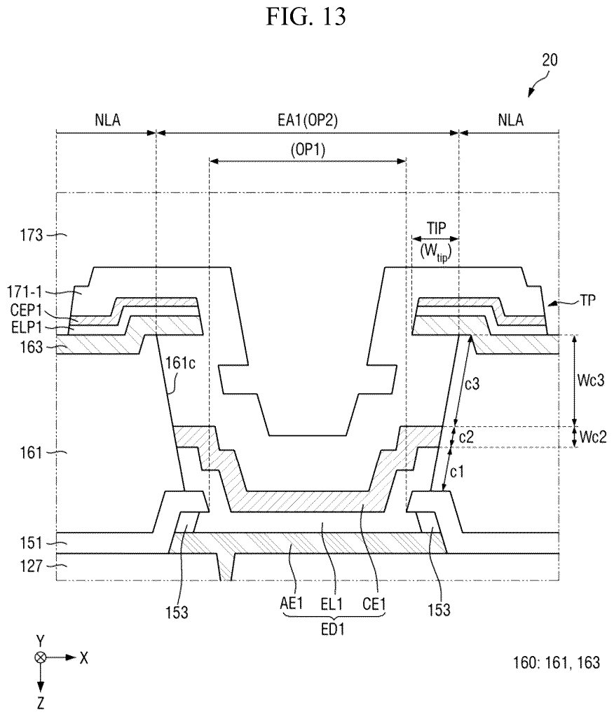

FIG. 13 is an enlarged schematic cross-sectional view of the first emission area EA1 in FIG. 12.

Referring to FIG. 13, the pixel defining layer 151 may be disposed on the second via layer 127 and the first anode AE1. The pixel defining layer 151 may overlap a second opening OP2 and may be spaced apart from the first anode AE1 in the third direction (Z-axis direction). The residual patterns 153 may be disposed between the pixel defining layer 151 and the first anode AE1. The residual patterns 153 may be disposed on sides of the first light emitting layer EL1 in the first direction (X-axis direction) to contact the first light emitting layer EL1 and may overlap the tips TIP of the bank structure 160 in the third direction (Z-axis direction).

The bank structure 160 may be located on the pixel defining layer 151. The bank structure 160 may include the first bank layer 161 and the second bank layer 163 including different metal materials and structures and playing different roles.

The first bank layer 161 may be located on the pixel defining layer 151 to contact the pixel defining layer 151. The first bank layer 161 may include a metal having high electrical conductivity, for example, aluminum (Al).

In some embodiments, the first bank layer 161 may include side surfaces 161c facing a first opening OP1. The side surfaces 161c of the first bank layer 161 may be inclined surfaces. In other words, the side surfaces 161c of the first bank layer 161 may be inclined between the first direction (X-axis direction) and the third direction (Z-axis direction). For example, each of the side surfaces 161c of the first bank layer 161 may include a structure that is more recessed than the pixel defining layer 151 in the first direction (X-axis direction).

The first light emitting layer EL1 and the first cathode CE1 may contact the side surfaces 161c of the first bank layer 161 according to an embodiment. In the display device 20, since the bank structure 160 includes the tips TIP, the first light emitting layer EL1 and the first cathode CE1 may be formed through deposition and photo pattern processes without using a fine metal mask in a manufacturing process. Therefore, the first light emitting layer EL1 and the first cathode CE1 may contact the side surfaces 161c of the first bank layer 161 in a portion overlapping the second opening OP2 in a plan view.

The first cathode CE1 according to an embodiment may cover a greater area of the side surfaces 161c of the first bank layer 161 than the first light emitting layer EL1. As described above, the first cathode CE1 and the first bank layer 161 may be electrically connected. As the area of contact between the first cathode CE1 and each side surface 161c of the first bank layer 161 increases, the electrical resistance of the display device 20 may decrease. As the thin-film density of the first cathode CE1 increases during a manufacturing process, the electrical resistance of the display device 20 may decrease. Accordingly, the first cathode CE1 may be required to be deposited to contact a large area of each side surface 161c of the first bank layer 161 and have a thin-film density during the manufacturing process. However, the first cathode CE1 may be required to be spaced apart from the second bank layer 163 to prevent leakage current defects.

The first cathode CE1 according to an embodiment may be manufactured by the sputtering apparatus 10 or the sputtering apparatus 30. As described above, each of the sputtering apparatus 10 and the sputtering apparatus 30 may include magnet members inside a target and cathode walls on a surface of the target to improve the density of plasma gas during a manufacturing process.

In some embodiments, each side surface 161c of the first bank layer 161 may include a first part c1, a second part c2, and a third part c3 depending on a structure contacting. The first part c1 may be a part in contact with the first light emitting layer EL1, the second part c2 may be a part in contact with the first cathode CE1, and the third part c3 may be a part in contact with the first inorganic layer 171-1.

As described above, the sputtering apparatus 10 may control the straightness and directionality of ionized target particles by adjusting the pressure of plasma gas during a manufacturing process. In other words, the area of the first cathode CE1 in contact with each side surface 161c of the first bank layer 161 may be adjusted according to the required characteristics of the display device 20.

For example, the area Wc2 of the second part c2 may be adjusted according to required characteristics. For example, the area Wc2 of the second part c2 may be adjusted to cover in a range of about 10% to about 95% of each side surface 161c of the first bank layer 161. As the contact area Wc2 of the second part c2 increases, the contact area Wc3 of the third part c3 may decrease.

The second bank layer 163 may be disposed on the first bank layer 161. The second bank layer 163 may include a material having a lower etch rate than an etch rate of the first bank layer 161. For example, the second bank layer 163 may include titanium (Ti).

In some embodiments, the second bank layer 163 may have the tips TIP protruding more than the side surfaces 161c of the first bank layer 161 toward the first emission area EA1, and a protruding distance Wₜᵢₚ of each tip TIP of the second bank layer 163 may be adjusted according to the required characteristics of the display device 20. For example, the protruding distance Wₜᵢₚ of each tip TIP may be in a range of about 0.1 μm to about 1.5 μm.

The first organic pattern ELP1 may be disposed on the second bank layer 163. The first organic pattern ELP1 may be disposed in a portion overlapping each protruding tip TIP of the second bank layer 163 in a plan view in the second opening OP2. The first organic pattern ELP1 may expose a portion of the second bank layer 163 in a portion in the non-emission area NLA. This structure may be formed by covering the entire surface of the second bank layer 163 with the first organic pattern ELP1 and etching a portion the first organic pattern ELP1 in a subsequent etching process during the process of manufacturing the display device 20. A protruding tip TP may be formed in the etched portion of the first organic pattern ELP1. The protruding tip TP may be covered by the second encapsulation layer 173.

The first electrode pattern CEP1 may be disposed on the first organic pattern ELP1. The first electrode pattern CEP1 may be disposed in a portion overlapping each protruding tip TIP of the second bank layer 163 in a plan view in the second opening OP2. The first electrode pattern CEP1 may expose a portion of the second bank layer 163 in the non-emission area NLA. This structure may be formed by covering the entire surface of the first organic pattern ELP1 with the first electrode pattern CEP1 and etching a portion the first electrode pattern CEP1 in a subsequent etching process during the process of manufacturing the display device 20. A protruding tip TP may be formed in the etched portion of the first electrode pattern CEP1. The protruding tip TP may be covered by the second encapsulation layer 173.

The first inorganic layer 171-1 may cover the first light emitting element ED1 and the first electrode pattern CEP1. The first inorganic layer 171-1 may contact the first cathode CE1 and the side surfaces 161c of the first bank layer 161 in the second opening OP2 and may cover the protruding tips TIP of the second bank layer 163. The first inorganic layer 171-1 may expose a portion of the second bank layer 163 in the non-emission area NLA. This structure may be formed by covering the entire surface of the first electrode pattern CEP1 with the first inorganic layer 171-1 and etching a portion the first inorganic layer 171-1 in a subsequent etching process during the process of manufacturing the display device 20. A protruding tip TP may be formed in the etched portion of the first inorganic layer 171-1. The protruding tip TP may be covered by the second encapsulation layer 173.

A sputtering apparatus according to an embodiment may improve plasma density during a manufacturing process by including protrusions and hollows on a surface of a target. Therefore, the sputtering apparatus may readily form a deposition layer with characteristics required by a display device of an embodiment.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A sputtering apparatus comprising:
a chamber in which a display device is placed and a deposition process is performed on the display device;
a gas supply part supplying plasma gas into the chamber;
a first target disposed in the chamber and facing the display device; and
a plurality of first magnet members disposed inside the first target, wherein
the first target comprises a first surface facing the display device and a second surface opposite the first surface and facing the plurality of first magnet members, and
the first target further comprises hollows and protrusions alternately repeated on the first surface.

2. The sputtering apparatus of claim 1, wherein
the first target has a long cylindrical shape, and
the first surface has a cogwheel shape.

3. The sputtering apparatus of claim 2, wherein the first target includes a metal for forming a cathode of the display device.

4. The sputtering apparatus of claim 2, wherein the first target includes a metal for forming a transparent or translucent thin-film electrode.

5. The sputtering apparatus of claim 2, wherein the first target functions as a cathode.

6. The sputtering apparatus of claim 2, wherein the first target has cathode walls facing each other by neighboring ones of the protrusions on the first surface.

7. The sputtering apparatus of claim 6, wherein
the first target forms a first magnetic field by the plurality of first magnet members, and
a density of the plasma gas increases around first magnetic field lines included in the first magnetic field.

8. The sputtering apparatus of claim 7, wherein
the first target forms a hollow cathode effect by the cathode walls, and
the density of the plasma gas increases around the cathode walls.

9. The sputtering apparatus of claim 1, further comprising:
a second target adjacent to the first target in a direction; and
a plurality of second magnet members disposed inside the second target,
wherein the second target comprises protrusions and hollows repeated on a surface of the second target.

10. The sputtering apparatus of claim 9, further comprising:
an alternating current (AC) power device connected to the first target and the second target.

11. The sputtering apparatus of claim 1, wherein
the display device comprises:
a substrate comprising an emission area and a non-emission area;
an anode on the emission area of the substrate;
a pixel defining layer on the non-emission area of the substrate;
a first bank layer on the pixel defining layer;
a second bank layer disposed on the first bank layer and comprising a tip which protrudes over a side surface of the first bank layer toward the emission area;
a light emitting layer disposed on the anode and contacting the side surface of the first bank layer; and
a cathode disposed on the light emitting layer and contacting the side surface of the first bank layer, and
an area of contact between the cathode and the side surface of the first bank layer is adjusted by adjusting a pressure of the plasma gas inside the chamber.

12. The sputtering apparatus of claim 11, wherein
the side surface of the first bank layer comprises a first part in contact with the light emitting layer and a second part in contact with the cathode, and
an area of the second part is adjusted in a range of about 10% to about 95% of the side surface of the first bank layer.

13. A sputtering apparatus comprising:
a chamber in which a display device is placed and a deposition process is performed on the display device;
a target disposed in the chamber and facing the display device;
a plurality of internal magnet members disposed inside the target; and
a gas supply part injecting plasma gas into the target,
wherein the target comprises a plurality of holes completely passing through the target.

14. The sputtering apparatus of claim 13, wherein the plasma gas is released from the inside of the target to the display device through the plurality of holes of the target.

15. The sputtering apparatus of claim 14, wherein the target further comprises a plurality of cathode walls neighboring each other in a direction with one of the plurality of holes interposed between adjacent ones of the plurality of cathode walls.

16. The sputtering apparatus of claim 15, wherein
a hollow cathode effect is formed between the adjacent ones of the plurality of cathode walls, and
a density of the plasma gas increases adjacent to the plurality of cathode walls.

17. A sputtering method for forming a cathode in a display device using a sputtering apparatus, the method comprising:
maintaining an inside of a chamber in a vacuum state using a vacuum pump and injecting plasma gas by a gas supply part;
forming plasma around a target by applying a cathode voltage to the target;
sputtering the target by the plasma gas and depositing ionized particles of the target on the display device as the cathode; and
adjusting characteristics of a deposition layer of the cathode by adjusting straightness of the ionized particles of the target by adjusting the pressure of the plasma gas,
wherein the target comprises protrusions and hollows alternately repeated on a surface of the target to increase a density of the plasma gas.

18. The sputtering method of claim 17, wherein
the target further comprises internal magnet members disposed in the target, and
the density of the plasma gas is increased by a magnetic field formed by the internal magnet members.

19. The sputtering method of claim 18, wherein
the target has cathode walls formed facing each other by neighboring ones of the protrusions formed on a surface of the target facing the display device, and
the density of the plasma gas is increased around the cathode walls by a hollow cathode effect formed by neighboring ones of the cathode walls.

20. The sputtering method of claim 19, wherein the straightness and directionality of the ionized particles that form the cathode are controlled by adjusting the pressure of the plasma gas inside the chamber.
